(19) United States
(12) Patent Application Publication
(10) Pub. No.: US 2026/0100342 A1
(43) Pub. Date: Apr. 9, 2026

(54) Rapid Process Chamber Pressure Modulation Using Chamber Pressure Control Ring with Micro Shutters

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/908,712

(22) Filed: Oct. 7, 2024

(51) Int. Cl. H01J 37/32

(52) U.S. Cl. CPC H01J 37/32834; C23C 16/4412; C23C 16/45557; C23C 16/45565; C23C 16/52; H01J 37/3244; H01J 37/32449; H01J 37/32495; H01J 2237/0213; H01J 2237/1825; H01J 2237/24585

(57) ABSTRACT

The present disclosure relates to a system and method for semiconductor manufacturing that utilizes a chamber pressure control ring equipped with integrated micro shutters. The system, managed by a proportional-integral-derivative (PID) control, enables rapid and precise modulation of chamber pressure, significantly outperforming conventional vacuum valve-based methods. This innovation improves process efficiency and reduces cycle times, particularly in advanced semiconductor processes such as atomic layer etching (ALE) and atomic layer deposition (ALD).

### FIELD OF THE INVENTION

This invention relates to systems and methods for rapidly modulating the pressure within process chambers. More specifically, the invention focuses on accelerating the modulation of vacuum process chamber pressure, which is essential for various applications such as etching and deposition in semiconductor manufacturing.

### BACKGROUND

Vacuum process chambers play a crucial role in semiconductor manufacturing, supporting processes like plasma-based and thermal-based etching and deposition. These processes rely on maintaining precise and stable chamber pressure, as fluctuations can affect process outcomes. The speed at which stable pressure is achieved is also a key factor for process efficiency.

Current methods for controlling chamber pressure mainly rely on two factors: (1) regulation of gas flow into the chamber by mass flow controllers (MFCs), and (2) removal of gases and reaction byproducts from the chamber by a vacuum pump and valve. The MFCs control gas flow through a gas distribution unit, often located at the top of the chamber, while the vacuum valve controls the gas extraction rate.

To monitor the chamber pressure, a manometer is used. When the pressure deviates from the target set in the process recipe, the position of the vacuum valve is adjusted to restore the desired pressure. Typically, this is done using proportional-integral-derivative (PID) control, a process that can take tens to hundreds of milliseconds, making the speed of valve adjustment a limiting factor in pressure modulation.

The increasing adoption of atomic layer deposition (ALD) and atomic layer etching (ALE) in semiconductor manufacturing highlights the need for faster and more precise pressure control. Current methods are not always sufficient for these techniques, leading to a demand for improved pressure modulation systems.

### SUMMARY OF THE INVENTION

This summary provides an overview of the invention but does not limit its scope to the features mentioned. The invention is not confined to solving the specific problems discussed in the background section.

In various embodiments, a process chamber includes a chamber body, a gas distribution unit connected to a gasbox, a chuck for supporting substrates during processing, and a vacuum pump and valve for removing gases, including reaction byproducts. A manometer measures the chamber pressure, and a pressure control system adjusts the pressure accordingly.

In all embodiments, the invention introduces a chamber pressure control ring, positioned between the chuck and the chamber body or between the chuck's supporting structure and the chamber body. This ring narrows the gap between the chuck and the chamber body, with specific apertures that house micro shutters. These shutters operate similarly to those in cameras.

In some embodiments, the micro shutters have one or more blades, controlled by a shutter actuator. The actuator adjusts the blades to control the size of the aperture, regulating gas flow through the opening. The system includes a motor and a mechanism that converts rotational motion into linear motion, which controls the shutter blades' positions.

In certain embodiments, the chamber pressure control ring incorporates a shutter layer, an actuation layer, and an electronics layer that receives control signals from the system controller. These signals direct the motor and shutter actuator to adjust the blades as needed.

In some implementations, the position of the vacuum valve above the pump is controlled by the system controller based on the process recipe requirements. Before gas enters the chamber, the valve remains in a fixed position.

Additionally, some embodiments provide for delivering the same electrical current to all motors, while others allow for variable currents to different motors, depending on process requirements.

The apertures in the chamber pressure control ring may be uniformly distributed in some designs, while other designs may use non-uniform spacing for optimal performance.

Compared to traditional chamber pressure control methods, the invention offers significant advantages. Conventional systems rely on adjusting the vacuum valve, which can take hundreds of milliseconds to stabilize the pressure. In contrast, the micro shutters in this invention adjust far more quickly, substantially reducing cycle times for ALD and ALE processes and lowering the overall cost of ownership.

### BRIEF DESCRIPTIONS OF THE DRAWINGS

The embodiments of the invention are further explained with reference to the following drawings:

FIG. 1: A schematic illustration of a process system utilizing conventional chamber pressure control methods.

FIG. 2: A schematic representation of an embodiment featuring a chamber pressure control ring designed for rapid pressure modulation.

FIG. 3A: A top-view schematic of the chamber pressure control ring in one embodiment.

FIG. 3B: A top-view schematic of the chamber pressure control ring in another embodiment.

FIG. 3C: A cross-sectional view of the chamber pressure control ring.

FIG. 4: A functional diagram showing the components and interactions within the chamber pressure control ring.

FIG. 5: A flowchart illustrating the steps for chamber pressure modulation using the chamber pressure control ring.

### DETAILED DESCRIPTION

The following detailed description provides specific embodiments to aid in understanding the invention. While particular examples are offered for clarity, various modifications and changes that fall within the scope of the appended claims are possible. Common processes, systems, and components are not described in exhaustive detail to prevent obscuring key aspects of the invention.

### Terms Defined as Follows

### Chamber Components and Structure

Process Chamber: A controlled environment where semiconductor manufacturing operations such as etching, or deposition are carried out.
Chamber Pressure Control Ring: A component positioned within the process chamber, designed to modulate gas flow and pressure via mechanical or electromechanical mechanisms, such as micro shutters.
Chuck: A structure within the process chamber that holds the substrate (e.g., silicon wafer) during processing. It can be a vacuum chuck or electrostatic chuck.
Chuck Support Structure: The supporting structure that provides mechanical reinforcement and utility supply to the chuck, often creating a ring-shaped space with the chamber body.
Shutter Layer: A layer within the chamber pressure control ring that houses the shutters and shutter actuators, responsible for modulating gas flow.
Actuation Layer: A layer within the chamber pressure control ring containing motors and conversion mechanisms that drive the movement of the shutters.
Electronics Layer: A layer within the chamber pressure control ring that contains electrical components, such as driver circuits and interconnects, for controlling the motors and actuators.

### Gas Flow and Pressure Control

Mass Flow Controller (MFC): A device that regulates the flow rate of gas into the process chamber.
Vacuum Valve: A valve that controls the extraction of gases from the process chamber, typically in conjunction with a vacuum pump, to maintain or adjust chamber pressure.
Gas Distribution Unit: A component connected to the gasbox that introduces gases into the process chamber, often in the form of a showerhead or injector.
Gas Conduction Aperture: An opening within the micro shutter whose size controls the rate of gas flow through the chamber pressure control ring.
Manometer: A pressure measurement device used to gauge the pressure inside the process chamber.
Steady-State Pressure: The target pressure within the process chamber, as defined by the process recipe, where the system operates under stable conditions.

### Shutters and Related Mechanisms

Micro Shutter: A device with movable blades that regulate gas flow by adjusting the size of a gas conduction aperture, functioning similarly to a camera shutter.
Blades (of the Micro Shutter): Movable parts of the micro shutter that adjust the size of the gas conduction aperture to control gas flow and pressure in the process chamber.
Shutter Actuator: A mechanism that drives the movement of the blades within the micro shutter to open or close the aperture, typically powered by a motor.
Rotation-to-Linear Conversion Mechanism: A mechanism that converts rotational movement of a motor axis into linear movement, enabling precise control of the shutter actuator.

### Power and Control Systems

Power Supply: The source of electrical power for the components of the chamber pressure control ring, which could be external or a battery-based system.
PID Control (Proportional-Integral-Derivative): A control algorithm that adjusts system parameters based on the current and past errors in chamber pressure measurements to achieve a desired setpoint.
System Controller: A control system that manages the operations of the chamber pressure control ring, including controlling motors, actuators, and adjusting gas flow based on feedback from the manometer.

### Process Operations

Process Recipe: A predefined set of instructions that dictate the operational parameters (e.g., gas flow, pressure, and timing) for conducting a semiconductor manufacturing process within the chamber.
Substrate: The material, often a silicon wafer, that is processed inside the chamber during semiconductor manufacturing.
Preventive Maintenance Procedure: A routine process that involves inspecting and maintaining equipment, such as replacing or recharging a battery in the power supply.

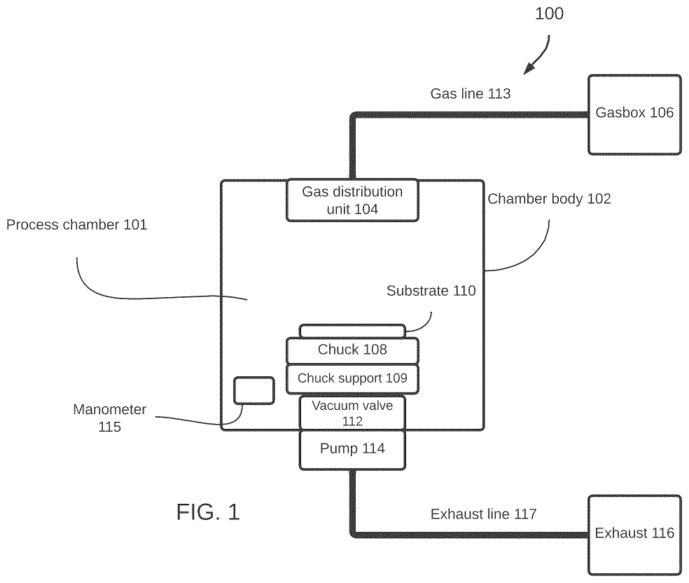

FIG. 1 illustrates a schematic diagram of a conventional process system (100) that includes a process chamber (101). The system (100) features a chamber body (102) that provides the vacuum environment needed for processing. A gas distribution unit (104), connected to a gasbox (106) via a gas line (113) and controlled by mass flow controllers (MFCs) (not shown), introduces gases into the chamber (101). The gas distribution unit (104) may be designed as a showerhead or an injector and is typically positioned at the top of the chamber.

A substrate support chuck (108) holds the substrate (110), often a silicon wafer, within the chamber (101) for processing. The chuck (108) can be a vacuum chuck or electrostatic chuck. The chuck is supported by a chuck support (109), which provides mechanical reinforcement and utility supply. The chuck support (109) is often round, creating a ring-shaped space with the chamber body (102).

Reaction byproducts and gases are removed from the chamber (101) through a vacuum pump (114) connected to an exhaust line (117) leading to the exhaust (116). A vacuum valve (112) plays a critical role in maintaining stable pressure inside the chamber during processing. The valve's position, combined with the pump's (114) capacity, regulates the gas extraction rate. A manometer (115) measures the pressure in the chamber, and any deviation from the target process pressure prompts an adjustment of the vacuum valve (112). This adjustment typically occurs over a span of several tens to hundreds of milliseconds, limiting the speed of chamber pressure modulation. As semiconductor manufacturing increasingly adopts atomic layer deposition (ALD) and atomic layer etching (ALE), faster pressure modulation becomes essential.

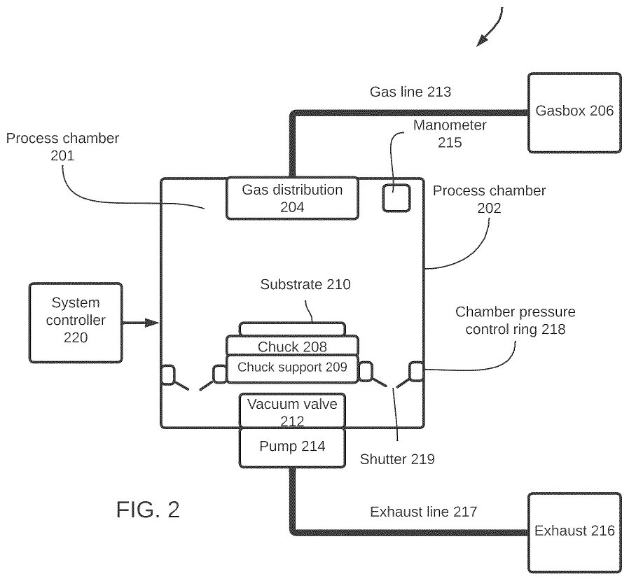

FIG. 2 illustrates a schematic of a process system (200), depicting an embodiment of the invention. The system (200) includes a process chamber (201) with a chamber body (202) that creates a vacuum environment. A gas distribution unit (204), connected to a gasbox (206) via a gas line (213) and controlled by MFCs (not shown), introduces gases into the chamber (201) through either the top or sidewalls.

A chuck (208) supports a substrate (210) within the chamber (201), which could be a vacuum chuck or an electrostatic chuck. The chuck support (209) reinforces the chuck (208) and provides utilities, often creating a ring-shaped space with the chamber body (202), though other configurations are also possible. Gases and byproducts are removed from the chamber (201) through a vacuum pump (212) and pump (214), which direct them via an exhaust line (217) to the exhaust (216).

The chamber pressure control ring (218) enables rapid modulation of the chamber pressure. The control ring (218), which may be made from materials such as metal, ceramics, or glass, contains orifices that regulate gas flow using a micro shutter (219), functioning similarly to camera shutters.

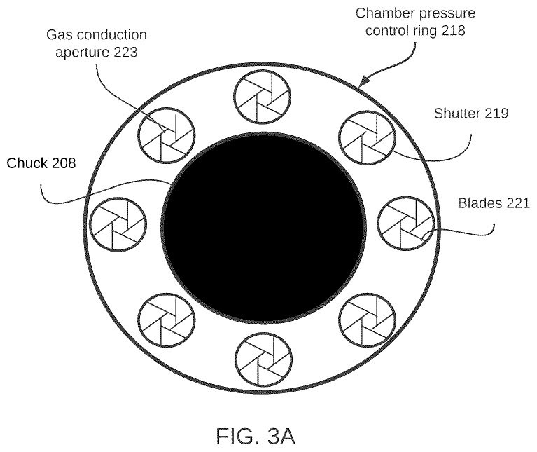

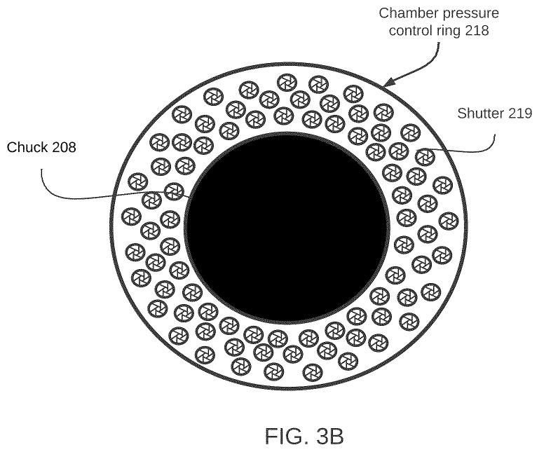

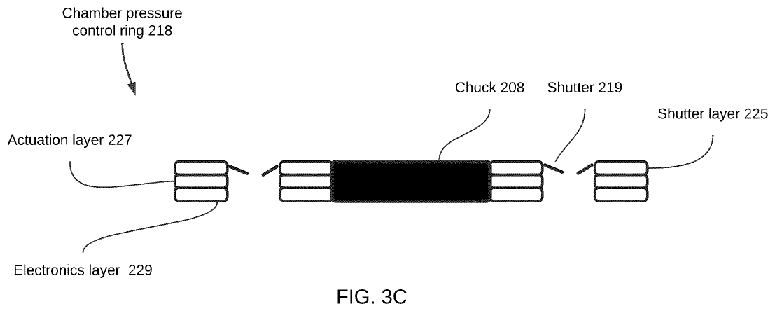

FIG. 3A shows a top view of the chamber pressure control ring (218) with shutters (219) in one embodiment. The shutters are composed of blades (221), whose positions determine the size of a gas conduction aperture (223). The size of this aperture controls gas conductance—larger apertures allow for higher conductance. The positions of the blades are adjusted by actuators driven by motors, enabling modification of the aperture size.

In some implementations, the blades (221) may be made from metals such as aluminum, with anodized or coated surfaces to resist harsh plasma environments. In other implementations, the blades may be heated to minimize byproduct deposition on their surfaces.

It is important to note that the term “ring” is used broadly in this context and may refer to circular, rectangular, or irregular shapes, depending on the configuration of the chuck and its support structure.

The size and number of shutters may also vary. FIG. 3B illustrates an alternative embodiment with smaller and more densely arranged shutters compared to the implementation shown in FIG. 3A. The shutters may be arranged uniformly or non-uniformly to compensate for process system (200) components that cause nonuniformities, such as the pump (214).

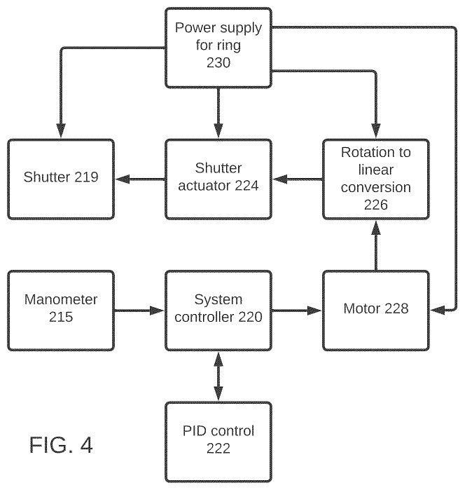

FIG. 3C provides a cross-sectional view of the chamber pressure control ring (218). In one embodiment, the ring (218) includes a shutter layer (225) that houses the shutters (219) and shutter actuators (224) (as shown in FIG. 4). The ring also includes an actuation layer (227), which contains motors (228). A rotation-to-linear conversion mechanism (226) can be located either in the shutter layer (225) or the actuation layer (227). Electronic components, such as driver circuits and interconnects, may be housed in an electronics layer (229). This implementation is exemplary, and various other configurations for integrating the components of the ring (218) are possible. All such variations fall within the scope of the present invention.

FIG. 4 is a functional diagram of the chamber pressure control ring (218), comprising a motor (228), a rotation-to-linear conversion mechanism (226), a shutter actuator (224), and a shutter (219). A current from a power supply (230) activates the motor (228), generating rotational movement along an axis. This rotational motion is converted into linear movement by the rotational-to-linear conversion mechanism (226), which actuates the shutter actuator (224) to synchronously move the blades (221). The movement of the motor axis determines the size of the gas conduction aperture (223) at the center of the shutter (219).

The system controller (220) manages the operations of the ring (218) based on pressure measurements taken by the manometer (215). The controller (220) uses a proportional-integral-derivative (PID) control (222) to adjust the size of the gas conduction aperture (223) as needed to bring the chamber pressure to the desired steady-state. This is achieved by modifying the currents supplied to the motors (228) based on the measurements from the manometer (215). In one implementation, all motors receive the same current, while in another implementation, different motors may receive varied current levels.

In some implementations, the power supply (230) for the ring may draw power from the chuck supply or the chamber body. In other cases, the power supply may be a battery that can be replaced or recharged during a preventive maintenance procedure.

The chamber pressure control ring (218) should be designed with sufficient mechanical strength, and its surface should be treated or coated to withstand harsh plasma environments.

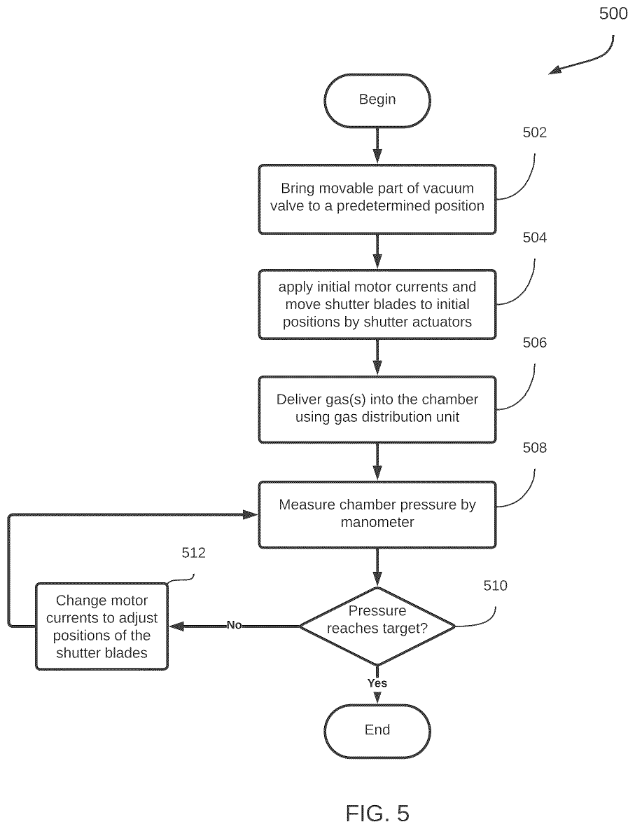

FIG. 5 presents a process (500) for quickly establishing a steady chamber pressure using the chamber pressure control ring (218). In step 502, the vacuum valve (212) is set to a predetermined position by the system controller. This position may be determined during a setup test or during the development of the process recipe. The valve position remains unchanged during the subsequent steps.

In step 504, initial currents are applied to the motors to move the shutter blades to their initial positions through the rotation-to-linear conversion mechanism (226) and the shutter actuator (224). In step 506, process gases are introduced into the process chamber (201), controlled by various MFCs through the gas distribution unit (204). The manometer (215) measures the chamber pressure in step 508.

If the measured pressure does not meet the target pressure in step 510, the system controller (220) iteratively adjusts the motor currents in step 512, using the PID control (222) if necessary. The positions of the blades are adjusted accordingly until the chamber pressure reaches the steady-state value specified by the process recipe.

1. A process chamber, comprising:
a chamber body configured for a vacuum environment;
a gas distribution unit configured to receive gases from a gasbox and disperse received gases within the process chamber;
a chuck configured to support a substrate;
a pump configured to extract gases from the chamber; and
a chamber pressure control ring, operational for chamber pressure modulation, wherein said chamber pressure control ring integrates a plurality of shutters, each of said shutters incorporates several blades, wherein positions of said blades determine gas conductance, wherein said positions of said blades are controlled by a rotational-to-linear conversion mechanism, which is connected to both a motor and an actuator, both of which direct the motion of said blades.

2. The chamber of claim 1, wherein the chamber pressure control ring is coupled to a system controller.

3. The chamber of claim 2, wherein the system controller includes a proportional-integral-derivative (PID) control.

4. The chamber of claim 1, wherein the placement of the chamber pressure control ring is placed within a gap separating the chuck from the chamber body.

5. The chamber of claim 1, wherein the chamber pressure control ring is located in an interspace between the chuck's a supporting structure and the chamber body.

6. The chamber of claim 1, further comprising a vacuum valve with a movable part that defines the gas conductance, wherein the position of the movable part remains unchanged during processing.

7. The chamber of claim 1, wherein the vacuum valve is absent.

8. The chamber of claim 1, wherein the chamber pressure control ring further comprises a shutter layer, an actuation layer and an electronics layer.

9. A method for regulating pressure within a process chamber, comprising:
providing a chamber pressure control ring, placed in a space between a chuck or a chuck support structure and a chamber body, wherein the ring comprises a plurality of shutters for modulating gas conductance by positioning of one or multiple blades, each shutter being coupled to a motor;
determining an initial current for each motor through a system controller;
deploying determined current to said motor by the system controller;
introducing one gas or more gases into the chamber, stipulated from the process recipe;
measuring chamber pressures using a manometer; and
adjusting the current delivered to said motor in response to the pressures measured by the manometer, wherein the current supplied to the motor dictates positions of blades, and the chamber pressure control ring including multiple orifices.

10. The method of claim 9, further comprising positioning a movable part of a vacuum valve located over a pump to a predetermined location prior to injecting gas into the process chamber, ensuring the position of the vacuum valve remains static throughout a processing.

11. The method as described in claim 9, further comprising a periodic measurement of the chamber pressures at a set frequency.

12. The method of claim 9, wherein the method further comprising supplying identical current to each motor.

13. The method of claim 9, wherein the method further comprising distinct current to different motors.

14. An apparatus for modulating pressure of a process chamber, comprising:
a ring-shaped structure containing multiple shutters, each shutter comprising one or multiple blades, wherein orientation of the blades being dictated by the current provided to an associated motor;
a shutter layer hosting the multiple shutters;
an actuation layer containing multiple motors coupled to the shutters through multiple rotation-to-linear movement mechanisms; and
an electronics layer for hosting electronic components and interconnects.

15. The apparatus of claim 14, wherein the apparatus is powered by a power supply including a battery.

16. The apparatus of claim 14, where positions of the blades are controlled by a synchronized operation of a shutter actuator.

17. The apparatus of claim 14, wherein the apparatus located in an interspace between a chamber's chuck and its main body.

18. The apparatus of claim 14, wherein the apparatus is located in an interspace between the chamber's chuck support structure and the chamber body.

19. The apparatus of claim 14, wherein the apparatus determines the chamber pressure through a proportional-integral-derivative (PID) control provided by a system controller involving additionally a vacuum valve, a pump and a manometer.

20. The apparatus of claim 14, wherein the apparatus further comprises plasma resistance surface, and the blades are heated.
